(19) United States
(12) Patent Application Publication
(10) Pub. No.: US 2019/0351441 A1
(43) Pub. Date: Nov. 21, 2019

(54) VIBRATING SPRAY APPLICATOR SYSTEM

(71) Applicant: Carlisle Fluid Technologies, Inc., Scottsdale, AZ (US)

(72) Inventor: Daniel Joseph Hasselschwert, Sylvania, OH (US)

(21) Appl. No.: 16/405,799

(22) Filed: May 7, 2019

Related U.S. Application Data
(60) Provisional application No. 62/671,898, filed on May 15, 2018.

(51) Int. Cl. B05B 12/00; G01C 3/06; G01R 19/00

(52) U.S. Cl. CPC B05B 12/004; G01R 19/0092; G01C 3/06

(57) ABSTRACT

A spray system includes a spray applicator configured to apply a fluid to a grounded target, an electrostatic charge system configured to apply an electrical charge to the fluid, and a vibration system configured to provide tactile feedback to an operator of the spray system based on at least one detected operating parameter of the spray system.

### CROSS-REFERENCE TO RELATED APPLICATION

This application claims priority from and the benefit of U.S. Provisional Patent Application No. 62/671,898, entitled “VIBRATING SPRAY APPLICATOR SYSTEM,” filed May 15, 2018, which is hereby incorporated by reference in its entirety for all purposes.

### BACKGROUND

The subject matter disclosed herein relates to spray applicators, and more particularly, to a vibrating spray system that provides feedback during operation of a spray applicator.

This section is intended to introduce the reader to various aspects of art that may be related to various aspects of the present disclosure, which are described and/or claimed below. This discussion is believed to be helpful in providing the reader with background information to facilitate a better understanding of the various aspects of the present disclosure. Accordingly, it should be understood that these statements are to be read in this light, and not as admissions of prior art.

Spray applicators, such as spray guns, are used to apply a coating of a liquid or other fluid to a wide variety of target objects. During operation, a user of the spray applicator may focus attention on several different factors and operating parameters, such as the angle of the spray applicator, distance of the spray applicator to the target, the time of spraying, the coverage of the spray, and so forth. It may be difficult for the user to observe all aspects of the spray operation in an effort to achieve a desired spray quality.

### BRIEF DESCRIPTION

Certain embodiments commensurate in scope with the originally claimed embodiments are summarized below. These embodiments are not intended to limit the scope of the claimed disclosure, but rather these embodiments are intended only to provide a brief summary of possible forms of the disclosed subject matter. Indeed, the disclosed embodiments may encompass a variety of forms that may be similar to or different from the embodiments set forth below.

In certain embodiments, a spray system includes a spray applicator configured to apply a fluid to a grounded target, an electrostatic charge system configured to apply an electrical charge to the fluid, and a vibration system configured to provide tactile feedback to an operator of the spray system based on at least one detected operating parameter of the spray system.

In certain embodiments, a spray system includes a spray gun configured to apply a fluid to a target, an electrostatic charge system of the spray gun, where the electrostatic charge system is configured to apply an electrical charge to the fluid, and a vibration system of the spray gun, where the vibration system is configured to provide tactile feedback to an operator of the spray system based on at least one detected operating parameter of the spray system.

In certain embodiments, a method of operating a spray system includes detecting an operating parameter of a spray system and generating tactile feedback with a vibration system of the spray system based on a detected value of the operating parameter. The operating parameter includes either a distance between a grounded target and a spray applicator configured to apply a fluid to the grounded target or a speed of the spray applicator during application of the fluid to the grounded target.

### BRIEF DESCRIPTION OF THE DRAWINGS

These and other features, aspects, and advantages of the present disclosure will become better understood when the following detailed description is read with reference to the accompanying drawings in which like characters represent like parts throughout the drawings, wherein:

FIG. 1 is a side view of an embodiment of a spray system spraying a target, in accordance with an aspect of the present disclosure;

FIG. 2 is a schematic view of an embodiment of the spray system of FIG. 1, in accordance with an aspect of the present disclosure; and

FIG. 3 is a flowchart of an embodiment of a process for the spray system of FIGS. 1 and 2 to generate tactile feedback, in accordance with an aspect of the present disclosure.

### DETAILED DESCRIPTION OF SPECIFIC EMBODIMENTS

One or more specific embodiments of the present disclosure will be described below. These described embodiments are only exemplary of the present disclosure. Additionally, in an effort to provide a concise description of these exemplary embodiments, all features of an actual implementation may not be described in the specification. It should be appreciated that in the development of any such actual implementation, as in any engineering or design project, numerous implementation-specific decisions must be made to achieve the developers' specific goals, such as compliance with system-related and business-related constraints, which may vary from one implementation to another. Moreover, it should be appreciated that such a development effort might be complex and time consuming, but would nevertheless be a routine undertaking of design, fabrication, and manufacture for those of ordinary skill having the benefit of this disclosure.

When introducing elements of various embodiments of the present disclosure, the articles “a,” “an,” “the,” and “said” are intended to mean that there are one or more of the elements. The terms “comprising,” “including,” and “having” are intended to be inclusive and mean that there may be additional elements other than the listed elements.

Embodiments of the present disclosure are generally directed to a spray system, and, more particularly, to a spray system configured to provide tactile feedback for a user of the spray system. Specifically, the spray system provides tactile feedback during operation of a spray applicator to optimize a quality of spray applied by the spray applicator. For example, the spray applicator may be a hand-held spray gun configured to emit a liquid, such as paint, to coat a targeted object. The spray applicator may be an electrostatic spray device (e.g., an electrostatic, handheld spray gun) configured to electrically charge the liquid such that the liquid attracts onto the object. During operation of the spray applicator, the user may hold the spray applicator (e.g., at a handle of the spray applicator) and aim a nozzle of the spray applicator at the target object. In certain embodiments, there may be a range of distances that the spray applicator should be held away from the object during spraying to optimally coat the object. If the spray applicator is held too close to the object, too much sprayed liquid may accumulate at a portion of the object and thus, the liquid may undesirably run down the target object. If the spray applicator is held too far away from the object, the spray may not reach parts of the object, which may result in an ineffective use of spray material. In either case, the object may be unevenly coated, thereby resulting in a substandard spray quality. In addition to the distance from the object, the quality of the spray coating may depend on the speed of the spray applicator moving along the object during spray operation. For example, moving the spray applicator too quickly or too slowly each may result in an uneven coating of the object with the spray material. Indeed, there may be other factors that also impact the quality of spray applied to a target object. As such, it may be a difficult task for an operator to achieve a desired quality of spray on the target object. Furthermore, if an uneven or substandard quality of coating is produced, further operations to correct the coating may be performed, thereby increasing the cost of resources and decreasing operational efficiency.

Thus, in accordance with certain embodiments of the present disclosure, it is presently recognized that there is a need for a spray system configured to notify a user of a quality of the user's spray operation during the spray operation. For example, a spray applicator may provide tactile feedback during the spraying operation. In one embodiment, the spray system may provide feedback to the user when spray applicator is too close and/or too far from the target object and/or when the spray applicator is moving too quickly and/or too slowly along the target object. As such, the spray system may provide feedback to the user without using visual mechanisms or features, which may divert the attention of the user away from the spraying operation. The spray system may also provide feedback to the user without using audible mechanisms or features, which may be suppressed by sounds from the spray operation environment. In some embodiments, the spray system may include a vibration system that is configured to vibrate to indicate a deficient distance and/or speed, such as at a constant or a pulsing vibration. While the present discussion describes use of a vibration system to provide feedback regarding distance and speed operation parameters during a spray operation, it will be appreciated that the disclosed vibration system may be used to provide feedback regarding other operational parameters of the spray operation, such as spray applicator angle, spray material usage, and so forth.

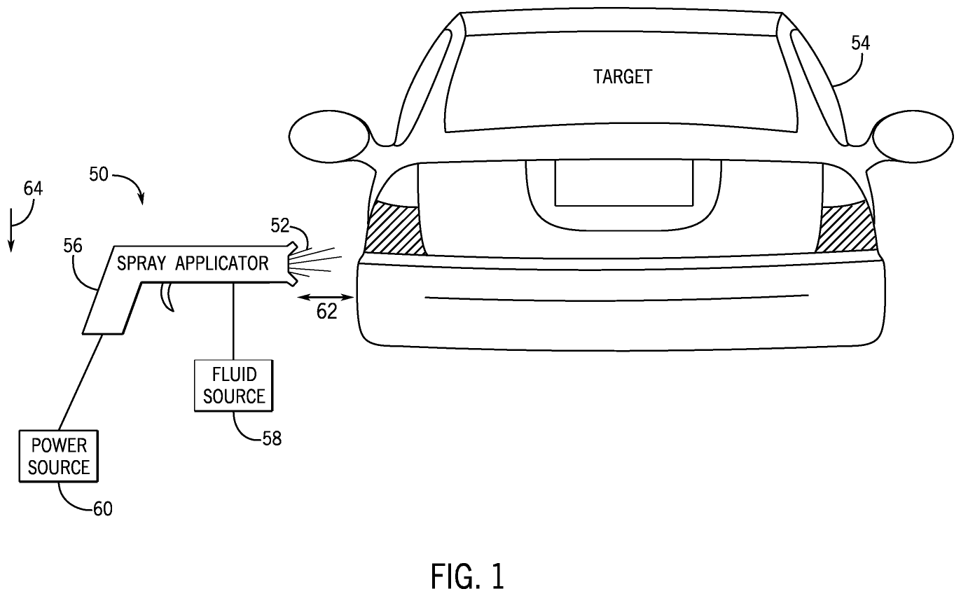

Turning to the drawings, FIG. 1 is a side view of an embodiment of a spray system 50 applying a spray 52 to a target 54. As illustrated in FIG. 1, the spray system 50 includes a spray applicator 56 that is configured to emit the spray 52. The spray applicator 56 is coupled to a fluid source 58 that supplies fluid, such as paint, to the spray applicator 56. As such, the spray 52 includes fluid from the fluid source 58. In some embodiments, the fluid source 58 is located external to the spray applicator 56 (e.g., above or below, adjacent to a nozzle). In addition, the spray applicator 56 is also coupled to a power source 60 that supplies power to the spray applicator 56 to operate the spray applicator 56. In some embodiments, the spray applicator 56 may be an electrostatic spray device, such as a manual spray gun, and the power source 60 may provide power for the spray applicator 56 to electrically charge the spray 52. That is, the spray 52 may be emitted at an electrical charge that is opposite to electrical charges of particles of the target 54. For example, the target 54 may include metal material with positively and negatively charged particles. The target 54 may be grounded such that the target 54 does not include an overall electrical charge. The spray applicator 56 may charge the spray 52, such that the spray 52 is positively charged when emitted out of the spray applicator 56. When the spray 52 contacts the target 54, the negatively charged particles of the target 54 attract the positively charged spray 52 to help the spray 52 adhere to the target 54. The power source 60 may also facilitate in the application (e.g., the emission) of the spray 52 or other operations of the spray applicator 56. In some embodiments, the power source 60 is located within the spray applicator 56, but in alternative embodiments, the power source 60 is located externally and coupled to the spray applicator 56 (e.g., via wiring).

During operation of the spray system 50, the spray applicator 56 is at a distance 62 away from the target 54. As such, when the spray 52 is emitted from the spray applicator 56, the spray 52 spreads when traveling the distance 62 before contacting the target 54. In various embodiments, there may be a desired or target value (or range of values) of the distance 62 for the spray applicator 56 to effectively and/or efficiently spray the target 54. For example, the distance 62 may be a length that enables the spray 52 to evenly coat the target 54 at a desired quality. If the distance 62 is too small, the spray 52 may accumulate in a certain area on the target 54, which may hinder the fluid of the spray 52 from drying in a desired manner or timeframe. As a result, the liquid spray 52 may undesirably run along or down the target 54 over areas of the target 54 that were not intended to be coated with the spray material during the spray operation. On the other hand, if the distance 62 is too large, the spray 52 may cover an area not intended to be coated on the target 54, or portions of the spray 52 may dry prior to contacting the target 54, thereby leaving portions of the target 54 uncoated that were originally intended to be coated with the spray material. Indeed, if the distance 62 is too great, the spray material may travel (e.g., via air current) to other areas of the spray environment that are not intended to be coated by the spray material. As such, there may be a range of values of the distance 62 between the spray applicator 56 and the target 54 for the spray applicator 56 to effectively and evenly coat the target 54 in a desired manner. The desired or target distance 62 may depend on various factors of the target 54 (e.g., material, texture), the spray system 50 (e.g., fluid substrate, spray speed, spray spread setting, spray applicator), and/or the environment (e.g., humidity, wind).

To detect the distance 62 between the spray applicator 56 and the target 54, the spray applicator 56 may be configured to measure and/or detect current generated by a flow path from charged spray 52 flowing from the spray applicator 56 to the target 54. The spray applicator 56 may apply a constant voltage during spraying operations, but the detected current may increase or decrease as the distance 62 varies. As such, by measuring the current, the spray applicator 56 may determine the distance 62 and subsequently provide feedback, as necessary, based on the determined distance 62.

In addition to the distance 62, the quality of coating applied by the spray system 50 may depend on a speed at which the spray applicator 56 moves along the target 54 during the spraying operation. Indeed, during the spraying operation, a user of the spray applicator may physically or manually move the spray applicator 56 to along an area of the target 54 to apply the spray material to the area. For example, the spray applicator 56 may move in a direction 64, illustrated as a vertical direction in FIG. 1. Similar to the distance 62, the speed at which the spray applicator 56 is moved by the user may determine a quality (e.g., evenness) of the coating applied to the target 54. A speed that is too slow may result in an undesired accumulation of the spray material on the target 54. Conversely, a speed that is too fast may result in an insufficient amount of spray 52 applied to one or more portions of the target 54. As such, there may be a range of desired speeds in which the spray applicator 56 may travel to effectively and evenly coat the target 54 with the spray material.

Since the quality of the spray coating may depend on at least the aforementioned factors (i.e., the distance 62 and the speed of the spray applicator 56), it is desirable for the spray system 50 to provide the user of the spray applicator 56 with feedback indicative that the distance 62 and/or the speed are adequate to yield desired coating results or quality. In particular, it is desirable to provide feedback to a user if the distance 62 and/or the speed of the spray applicator 56 relative to the target 54 are within an acceptable, target, or desired range. Additionally, as the user may be visually focused during the spraying operation (e.g., focused on the position and/or speed of the spray applicator 56 relative to the target 54, the emission of the spray material from the spray applicator 56), and as the environment of the spraying operation may be noisy, feedback may be more easily discerned by the user using a tactile system.

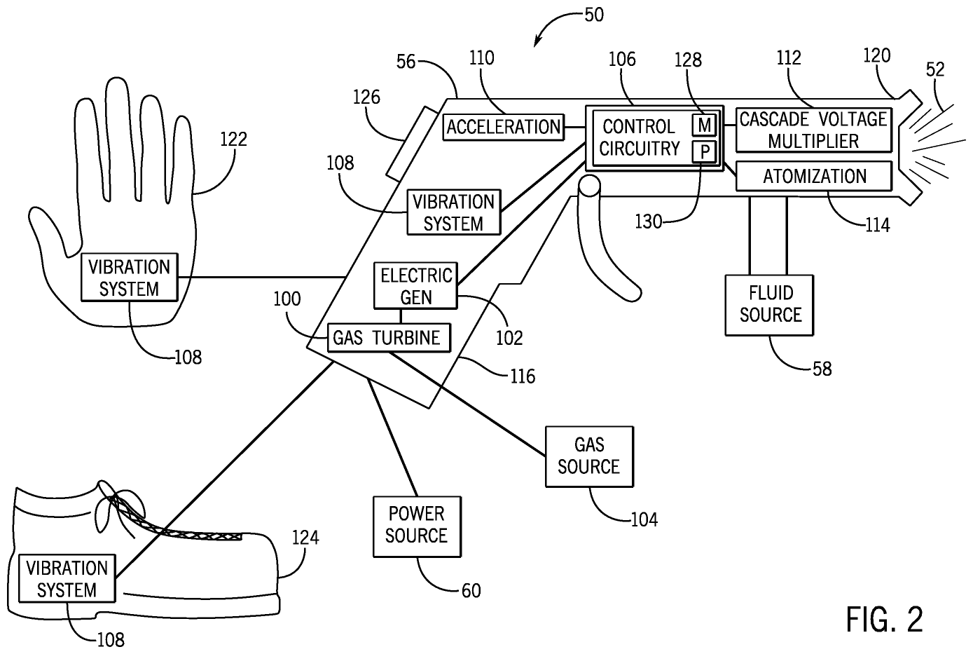

FIG. 2 is a schematic of an embodiment of the spray system 50 that is configured to provide feedback, such as tactile feedback, to a user of the spray system 50. As illustrated in FIG. 2, the spray system 50 includes the spray applicator 56. The spray applicator 56 includes a gas turbine 100 configured to power an electric generator 102. The gas turbine 100 may receive fluid from a gas source 104, which supplies gas, such as nitrogen, oxygen, carbon dioxide, another gas, or any combination thereof. The fluid from the gas source 104 drives the gas turbine 100 to rotate and produce rotational energy. The gas turbine 100 transfers the rotational energy to the electrical generator 102, which then converts the rotational energy into electrical energy. The electrical generator 102 thus provides electrical power to a control circuitry 106. Additionally or alternatively, the power source 60 may directly supply electrical power for the spray applicator 56 to power the control circuitry 106. Subsequently, the control circuitry 106 may supply power to other components of the spray applicator 56, such as a vibration system 108, an accelerometer 110, a cascade voltage multiplier 112, and an atomization assembly 114.

When powered, the spray applicator 56 is configured to spray fluid supplied via the fluid source 58. The user may pull a trigger 118 that initiates fluid to flow from the fluid source 58 into the spray applicator 56. For example, the fluid source 58 may be a pressurized container filled with fluid and pulling the trigger 118 may open the fluid source 58 such that the pressurized fluid flows as a steady stream into the spray applicator 56. After flowing into the spray applicator 56, the fluid is electrostatically charged by the cascade voltage multiplier 112, which receives electrical power from the control circuitry 106 to convert into greater voltage power. The cascade voltage multiplier 112 then uses the produced voltage power to electrostatically charge the fluid. The charged fluid may then be atomized by the atomization assembly 114 that is configured to convert the stream of fluid into the spray 52 upon exiting a nozzle 120 of the spray applicator 56. That is, the fluid stream is broken up into finer particles and exits the nozzle 120 in a widespread profile to cover a greater area upon contacting the target 54. In some embodiments, the atomization assembly 114 may include an air atomizer, airless atomizer, rotary atomizer, another suitable atomizer, or any combination thereof. Upon exiting the nozzle 120, the spray 52 maintains its electric charge and, upon contacting the grounded target 54, the spray 52 generates a current flow path from the spray applicator 56 to the target 54.

As discussed above, the spray system 50 is configured to measure and/or detect the produced current flow path and provide tactile feedback to the user of the spray applicator 56 based on the current. The spray system 50 may provide tactile feedback via the vibration system 108, which is configured to produce vibrations when powered and/or instructed by the control circuitry 106. For example, the vibration system 108 may include vibration motors that are configured to vibrate when powered or instructed. In some embodiments, the spray applicator 56 may be a spray gun and the vibration system 108 may be located within the spray applicator 56, such as within a handle 116 of the spray applicator 56. As such, during operation, when the user holds the spray applicator 56 at the handle 116, the vibration system 108 may generate tactile feedback that is felt by the user's hand gripping the handle 116. In additional or alternative embodiments, the vibration system 108 may be located external to the spray applicator 56. For example, the vibration system 108 (e.g., a vibrational motor or other vibrational feature) may be integrated with a glove 122, a shoe 124, a wristband, an armband, a belt clip module, or integrated with another article of clothing. The user may wear such articles of clothing when operating the spray system 50. Thus, the user may readily sense a vibration generated by the vibration system 108. The vibration system 108 (e.g., the vibration motor) may be coupled to the control circuitry 106 via wiring, such that the control circuitry 106 directly powers or actuates the vibration system 108. In this manner, when tactile feedback is desired, the control circuitry 106 powers or actuates the vibration system 108 to vibrate and provide the tactile feedback. In additional or alternate embodiments, the vibration system 108 is communicatively coupled to the control circuitry 106 without the use of wires or other physical connections. In these embodiments, the vibration system 108 may include its own power source and/or control system and may be configured to communicate with the control circuitry 106 or other component of the spray system. For example, to produce tactile feedback, the control circuitry 106 may wirelessly transmit data to the vibration system 108 to cause the vibration system 108 to produce the tactile feedback.

The settings of the tactile feedback may be controllable or adjustable by the user. For example, the spray applicator 56 may include a control panel 126, such as near the handle 116 of the spray applicator 56 but away from where the user holds the handle 116. The user may use the control panel 126 to adjust operational settings of the spray applicator 56 and/or vibration system 108, such as the intensity of the tactile feedback, the type of tactile feedback (e.g., constant vibration or pulsing vibration), or other aspects of the tactile feedback. Additionally, the user may use the control panel 126 to adjust other settings of the spray applicator 56, such as the speed and/or the spread of the spray 52 as the spray 52 exits the nozzle 120. As such, the control panel 126 may be communicatively coupled to the control circuitry 106, which is configured to adjust settings of the spray system 50 as inputted by the user.

To facilitate operation of the spray system 50, the control circuitry 106 includes a memory 128 and a processor 130. In certain embodiments, the memory 128 may be configured to store instructions that are loadable and executable by the processor 130. The memory 128 may be volatile (e.g., random access memory (RAM)) and/or non-volatile (e.g., read-only memory (ROM) or flash memory). Additionally, the memory 128 may include multiple different types of memory, such as static random access memory (SRAM), dynamic random access memory (DRAM), or ROM. The memory 128 may also include removable storage and/or non-removable storage including, but not limited to, magnetic storage, optical disks, and/or tape storage. The processor 130 is configured to execute the instructions stored by the memory 128 to control operations of the spray system 50, such as controlling when to generate tactile feedback provided by the vibration system 108.

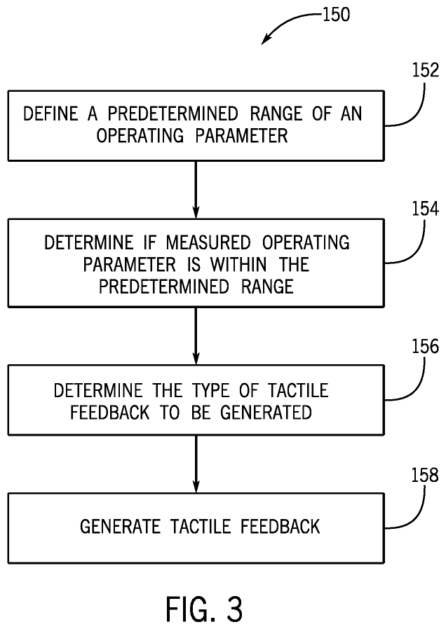

As mentioned above, in order to induce the vibration system 108 to produce tactile feedback, the spray system 50 is configured to monitor operating parameters of the spraying operation, such as the current flow generated by the electrically charged fluid and/or the speed that the spray applicator 56 moves. FIG. 3 is a flowchart illustrating an embodiment of a process 150 for the spray system 50 to generate tactile feedback. In block 152, a predetermined value or range of values for an operating parameter is selected for the spray system 50. The selected operating parameter may be calculated in different manners, depending on if the operating parameter is the distance 62, the speed of the spray applicator 56, or another operating parameter.

For example, if the distance 62 is the operating parameter on which tactile feedback is based, the predetermined range of values may be a range of current values, described above, indicative of a target or desired distance 62 between the spray applicator 56 and the target object 54. As mentioned above, current flow from the spray applicator 54 to the target object 54 via the spray 52 may vary depending on the distance 62. Therefore, measuring the current flow may indirectly measure and/or determine the distance 62. For example, as the distance 62 decreases, the measured current increases. Conversely, as the distance 62 increases, the measured current decreases. In some embodiments, the cascade voltage multiplier 112 is configured to measure the current flow and transmit the measurement or data indicative of the measurement to the control circuitry 106. The control circuitry 106 may then determine if the measurement is within the predetermined range of currents that represents the range of target or desired distances 62.

If the speed of the spray applicator 56 is the operating parameter on which tactile feedback is based, the predetermined range of values may be a range of target or desired speeds. In some embodiments, the spray applicator 56 may calculate the speed based on feedback from the accelerometer 110. The calculations by the spray applicator 56 may indicate the speed at which the spray applicator 56 is moving during spraying operation. The control circuitry 106 may compare the measured or detected speed with a predetermined range of speeds that represents the range of target or desired speeds.

The target or desired values or range of values of the operating parameters on which tactile feedback is based may depend on features of the spray 52, the target 54, and the spraying environment. In some embodiments, the predetermined range may be determined during a calibration phase prior to the spraying operation to determine the range of target or desired operating parameters. For example, the spray applicator 56 may spray the target 54 at various distances 62, and, afterwards, the quality of the spray coating applied to the target 54 may be analyzed (e.g., for amount, evenness, coverage). The distances 62 that include the desired, target, or preferred quality may be determined and, accordingly, the measured currents at such identified distances 62 may be used as the predetermined values (e.g., to define a range of values). A similar calibration phase may be used to determine the range of speeds. That is, the user may evaluate the quality of the spray coating applied to the target 54 after moving the spray applicator 56 at different speeds during a spraying operation. After determining the operating parameter (e.g., speed) values that produce the desired, target, or preferred quality of spray, the user may input such values into the control panel 126. The spray system 50 may then use the values to set the predetermined range of the corresponding operating parameter.

Additionally or alternatively, the user may input features or characteristics of the spraying operations. As an example, the user may input the features of the spray 52 (e.g., substrate, material composition, type of fluid), the target 54 (e.g., the material), and/or the environment (e.g., the humidity, temperature). The control panel 126 may then use the input information to automatically generate the range of desired or target distances 62 and/or the range of desired or target speeds, such as by using historical data (e.g., a lookup table or database) based on spraying operations with similarly input information. As such, the user may forego performing the calibration phase to determine the predetermined range before each spraying operation.

During spraying operation, the control circuitry 106 may determine if the determined operating parameter is within a predetermined range of values, as indicated by block 154. For example, the spray system 50 may measure the current flow, such as via the cascade voltage multiplier 112, which the control circuitry 106 then receives and compares to the predetermined range associated with current values. Additionally, the control circuitry 106 may calculate speed based on feedback from the accelerometer 110, and then compare the speed to the predetermined range associated with speed value.

After determining if the particular operating parameter is within the corresponding predetermined range, the control circuitry 106 may determine if tactile feedback is appropriate. For example, the control circuitry 106 may determine a type of tactile feedback that should be generated, as indicated by block 156. The type of tactile feedback (e.g., for a particular circumstance or detection) may be pre-determined or selected by the user. In some embodiments, the user may input when vibrations occur and the vibration settings (e.g., vibration intensities, vibration types) related to whether or not the operating parameter is within the predetermined range. For example, the user may input a constant vibration of the vibration system 108 for instances when the operating parameter is outside of the predetermined range. Additionally, the user may input different vibration settings to distinguish between instances when the distance 62 is outside its predetermined range and when the distance 62 is inside its predetermined range. By way of example, the user may designate constant vibration feedback for when the detected distance 62 is outside of the predetermined values and may designate pulsing vibration feedback for when the detected distance 62 is within the predetermined values. In another embodiment, the vibration system 108 may output no vibration feedback when the detected distance 62 is within the predetermined values, but may output selected vibration feedback (e.g., pulsating vibrations, constant vibrations) when the detected distance 62 is outside the predetermined values. The control circuitry 106 may be similarly configured based on user preferences for tactile feedback associated with the detected speed of the spray applicator 56.

In some embodiments, the settings of the vibration feedback produced by the vibration system 108 may also be adjusted based on the degree or particular detected value of detected operating parameter. For example, the vibration feedback may increase in intensity as the detected distance 62 becomes further outside of the range of predetermined distance values. In this manner, the tactile feedback may indicate to the user the amount of adjustment or correction to be made to the distance 62 (e.g., via movement of the spray applicator 56) to cause the detected distance 62 to be within the predetermined range. Additionally or alternatively, vibration settings may be selected to cause the vibration feedback to vary depending on if the detected operating parameter is above or below the predetermined range. As an example, the vibration feedback may be at a first intensity to indicate the detected operating parameter is greater than the predetermined range of values, and the vibration feedback may be at a second intensity to indicate the detected operating parameter is less than the predetermined range of values. The settings may be determined by the user via input into the control panel 126. As will be appreciated, additional or alternative embodiments may alter the vibration settings to produce different combinations of vibration settings. Such features may also be inputted by the user.

After determining the type of tactile feedback to be generated via comparing the detected operating parameter to the predetermined range of operating parameter values, the spray system 50 may generate the associated tactile feedback at the appropriate time. As discussed above, the tactile feedback may include powering vibrating motors of the vibration system 108 such that the motors vibrate. In an embodiment where there are several vibration systems 108, the user may input that different vibration systems 108 (e.g., different vibration motors) correspond to different detected operating parameters. As an example, a first vibration system 108 may be located on the glove 122, and a second vibration system 108 may be located on the shoe 124. The user may configure the spray system 50 such that the first vibration system 108 corresponds to the distance 62 and the second vibration system 108 corresponds to the speed. As such, the user may sense vibration in the glove 122 that corresponds to the determination of the distance 62, and the user may sense vibration in the shoe 124 that corresponds to the determination of the speed.

The vibration system 108 may also be configured to vibrate in response to detecting other operating parameters related to the spraying operation. For example, the spray system 50 may be configured to detect the angle that the spray applicator 56 is tilted with respect to the target 54 (e.g., which may be detected by the accelerometer 110), the amount of fluid remaining in the fluid source 58 (e.g., when the fluid is below a certain amount), or other aspects of the spray system 50. Accordingly, the vibration system 108 may be configured to send vibrations related to such aspects that further notifies the user during spraying operations. Such tactile feedback for other operating parameters may be similar configured in the manners described above with respect to distance 62 and speed of the spray applicator 56.

As will be appreciated, the control circuitry 106 may be configured to perform the process 150. For example, the memory 128 may include instructions of the steps described in block 152 and block 154 during spraying operations, and the processor 130 may be programmed to perform such steps stored in the memory 128. It should be appreciated that additional steps not mentioned may be performed in the process 150, such as before block 152, after block 154, between block 152 and block 154, or concurrently with block 152 and block 154. As an example, the control circuitry 106 may record how long the detected operating parameters are within the predetermined range of parameters and/or the percentage of time the detected operating parameters are within the predetermined range of parameters.

While the disclosure may be susceptible to various modifications and alternative forms, specific embodiments have been shown by way of example in the drawings and have been described in detail herein. However, it should be understood that the disclosure is not intended to be limited to the particular forms disclosed. Rather, the disclosure is to cover all modifications, equivalents, and alternatives falling within the spirit and scope of the disclosure as defined by the following appended claims.

1. A spray system, comprising:
a spray applicator configured to apply a fluid to a grounded target;
an electrostatic charge system configured to apply an electrical charge to the fluid; and
a vibration system configured to provide tactile feedback to an operator of the spray system based on at least one detected operating parameter of the spray system.

2. The spray system of claim 1, wherein the at least one detected operating parameter comprises a distance from the spray applicator to the grounded target.

3. The spray system of claim 2, wherein the distance is calculated based on a current of the electrical charge applied to the fluid.

4. The spray system of claim 3, wherein the spray applicator comprises a cascade voltage multiplier configured to determine the current of the electrical charge applied to the fluid.

5. The spray system of claim 1, wherein the at least one operating parameter comprises a speed of the spray applicator relative to the grounded target during operation of the spray system and during application of the fluid to the grounded target.

6. The spray system of claim 5, wherein the spray applicator comprises an accelerometer, and the speed is calculated based on feedback from the accelerometer.

7. The spray system of claim 1, wherein the vibration system comprises a vibration motor.

8. The spray system of claim 7, wherein the spray applicator comprises a spray gun, and the vibration motor is integrated with a handle of the spray gun.

9. The spray system of claim 1, wherein the vibration system is configured to provide the tactile feedback to the operator of the spray system when the at least one detected operating parameter is outside of a range of predetermined values.

10. The spray system of claim 9, wherein the vibration system is configured to provide additional tactile feedback to the operator of the spray system when the at least one detected operating parameter is inside of the range of predetermined values.

11. The spray system of claim 1, wherein the vibration system comprises a vibration component configured to vibrate based on the at least one detected operating parameter, wherein the vibration component is integrated with an article of clothing.

12. A spray system, comprising:
a spray gun configured to apply a fluid to a target;
an electrostatic charge system of the spray gun, wherein the electrostatic charge system is configured to apply an electrical charge to the fluid;
a vibration system of the spray gun, wherein the vibration system is configured to provide tactile feedback to an operator of the spray gun based on at least one detected operating parameter of the spray gun.

13. The spray system of claim 12, wherein the vibration system is integrated with a handle of the spray gun.

14. The spray system of claim 12, comprising an accelerometer of the spray gun, wherein the at least one detected operating parameter comprises a speed of the spray gun relative to the target during application of the fluid to the target, wherein the speed is calculated based on feedback from the accelerometer.

15. The spray system of claim 12, comprising a cascade voltage multiplier of the spray gun configured to detect a current of the electrical charge applied to the fluid, wherein the at least one detected operating parameter comprises a distance of the spray gun to the target, wherein the distance is calculated based on the detected current.

16. A method of operating a spray system, comprising:
detecting an operating parameter of a spray system, wherein the operating parameter comprises a distance between a grounded target and a spray applicator configured to apply a fluid to the grounded target or a speed of the spray applicator during application of the fluid to the grounded target; and
generating tactile feedback with a vibration system of the spray system based on a detected value of the operating parameter.

17. The method of claim 16, wherein generating tactile feedback comprises generating a vibration within the spray applicator.

18. The method of claim 16, wherein generating the tactile feedback comprises generating the tactile feedback when the detected value of the operating parameter is outside a range of predetermined values of the operating parameter.

19. The method of claim 18, comprising generating an additional tactile feedback when the detected value of the operating parameter is inside the range of predetermined values.

20. The method of claim 16, wherein detecting the operating parameter comprises measuring a current applied to the fluid by the spray applicator.
